(19) United States
(12) Patent Application Publication
(10) Pub. No.: US 2026/0024728 A1
(43) Pub. Date: Jan. 22, 2026

(54) PROCESSING APPARATUS AND PROCESSING METHOD

(71) Applicant: Tokyo Electron Limited, Tokyo (JP)

(72) Inventor: Hiroki MURAKAMI, Yamanashi (JP)

(21) Appl. No.: 19/248,743

(22) Filed: Jun. 25, 2025

(30) Foreign Application Priority Data
Jul. 16, 2024 (JP) 2024-113553

(51) Int. Cl. H01J 37/32

(52) U.S. Cl. CPC H01J 37/32449; H01J 37/32522; H01J 2237/3341; H01J 2237/3387

(57) ABSTRACT

A technology capable of achieving both of reduction of a thermal history and improvement of the reactivity of a processing gas is provided. A processing apparatus according to one embodiment of the present disclosure includes: a processing chamber forming a processing space in which a plurality of substrates are processed; a plasma forming part configured to form a plasma in a plasma formation space communicating with the processing space; a first gas nozzle configured to supply a first processing gas into the processing space; and a second gas nozzle configured to supply a second processing gas into the plasma formation space. The second gas nozzle includes a gas heater configured to heat the second processing gas in the second gas nozzle.

### CROSS-REFERENCE TO RELATED APPLICATION

The present application claims priority under 35 U.S.C. § 119 to Japanese Patent Application No. 2024-113553, filed Jul. 16, 2024, the contents of which are incorporated herein by reference in their entireties.

### BACKGROUND OF THE INVENTION

### Field of the Invention

The present disclosure relates to a processing apparatus and a processing method.

### Description of the Related Art

A disclosed technology removes a silicon oxide film formed on a substrate by repeating a step of supplying a fluorine-containing gas to the substrate and a step of exposing the substrate to a plasma of a gas containing ammonia alternately a plurality of times (see, for example, Japanese Patent Application Laid-Open Publication No. 2020-53615).

### SUMMARY OF THE INVENTION

A processing apparatus according to one embodiment of the present disclosure includes: a processing chamber forming a processing space in which a plurality of substrates are processed; a plasma forming part configured to form a plasma in a plasma formation space communicating with the processing space; a first gas nozzle configured to supply a first processing gas into the processing space; and a second gas nozzle configured to supply a second processing gas into the plasma formation space, wherein the second gas nozzle includes a gas heater configured to heat the second processing gas in the second gas nozzle.

### BRIEF DESCRIPTION OF THE DRAWINGS

FIG. 1 is a vertical cross-sectional view showing a processing apparatus according to an embodiment;

FIG. 2 is a horizontal cross-sectional view showing the processing apparatus according to an embodiment;

FIG. 3 is a cross-sectional view showing an example of a gas nozzle provided in a processing apparatus according to an embodiment;

FIG. 4 is a timing chart showing a processing method according to a first example of an embodiment; and

FIG. 5 is a timing chart showing a processing method according to a second example of an embodiment.

### DETAILED DESCRIPTION OF THE DISCLOSURE

Hereinafter, non-limiting exemplary embodiments of the present disclosure will be described with reference to the attached drawings. In all of the attached drawings, the same or corresponding members or parts will be denoted by the same or corresponding reference numerals, and duplicate descriptions will be omitted.

### [Processing Apparatus]

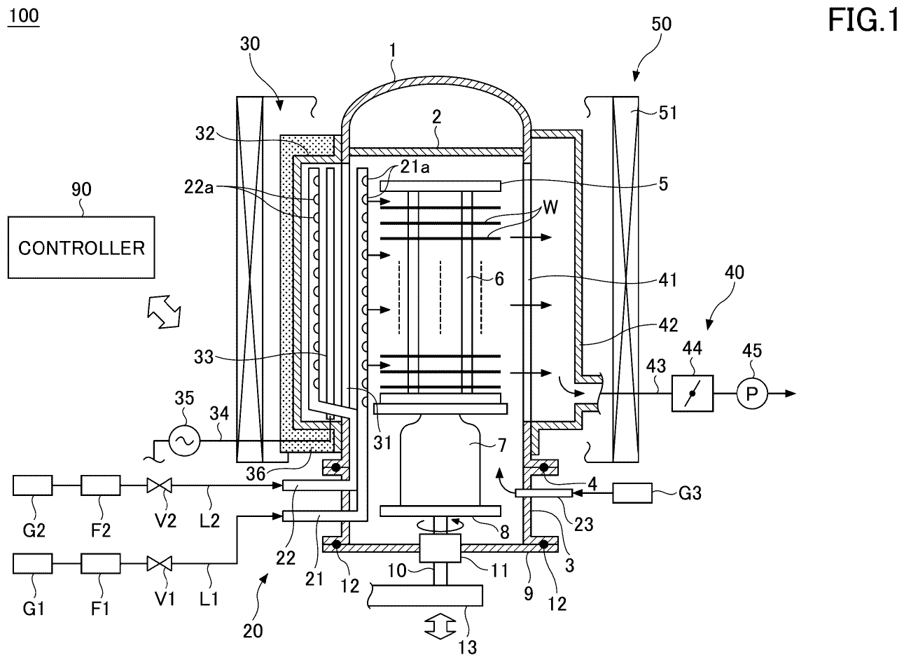

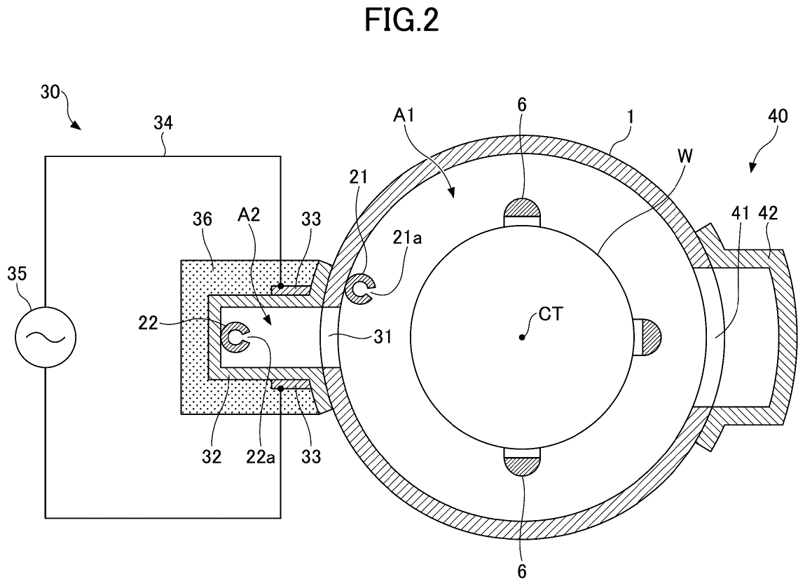

A processing apparatus 100 according to an embodiment will be described with reference to FIGS. 1 and 2. FIG. 1 is a vertical cross-sectional view showing the processing apparatus 100 according to the embodiment. FIG. 2 is a horizontal cross-sectional view showing a processing apparatus 100 according to an embodiment.

The processing apparatus 100 includes a processing chamber 1, a gas supply 20, a plasma forming part 30, a gas exhaust part 40, a chamber heating part 50, and a controller 90.

The processing chamber 1 forms a processing space A1 inside. In the processing space A1, various processes are performed on a plurality of substrates W. The various processes include, for example, a film forming process. The various processes may include an etching process. The processing chamber 1 has a vertically-long cylindrical shape having a ceiling and opened at the lower end. The processing chamber 1 is formed of, for example, quartz. A ceiling plate 2 is provided in the processing chamber 1 near the upper end of the processing chamber 1, and a region under the ceiling plate 2 is sealed. The ceiling plate 2 is formed of, for example, quartz. A cylindrical metal manifold 3 is joined to the opening at the lower end of the processing chamber 1 via a seal member 4. The seal member 4 is, for example, an O-ring.

The manifold 3 supports the lower end of the processing chamber 1. A boat 5 is inserted into the processing chamber 1 from under the manifold 3. The boat 5 holds a plurality of (for example, 25 to 150) substrates W in an arranged state. The boat 5 holds a plurality of (for example, 25 to 150) substrates W substantially horizontally at intervals along the vertical direction. The boat 5 is formed of, for example, quartz. The boat 5 includes, for example, three supports 6, and the plurality of substrates W are supported in grooves formed in the supports 6.

The boat 5 is mounted on a rotating table 8 via a heat insulation cylinder 7. The heat insulation cylinder 7 is formed of, for example, quartz. The heat insulation cylinder 7 inhibits heat dissipation from the opening at the lower end of the manifold 3. The rotating table 8 is supported on a rotary shaft 10. The opening at the lower end of the manifold 3 is opened and closed by a cover 9. The cover 9 is formed of, for example, a metal material, such as stainless steel and the like. The rotary shaft 10 penetrates the cover 9.

A magnetic fluid seal 11 is provided at a part that is penetrated by the rotary shaft 10. The magnetic fluid seal 11 airtightly seals and rotatably supports the rotary shaft 10. A seal member 12 is provided between the periphery of the cover 9 and the lower end of the manifold 3 for maintaining airtightness in the processing chamber 1. The seal member 12 is, for example, an O-ring.

The rotary shaft 10 is attached to an end of an arm 13 supported by a elevation mechanism, such as a boat elevator or the like. When the arm 13 is moved upward or downward, the boat 5, the heat insulation cylinder 7, the rotating table 8, and the cover 9 are moved upward or downward integrally with the rotary shaft 10, and are inserted into or removed from the processing chamber 1.

The gas supply 20 supplies various gases into the processing chamber 1. The gas supply 20 includes, for example, a gas nozzle 21, a gas nozzle 22, and a gas nozzle 23. The gas nozzle 21 is an example of a first gas nozzle, and the gas nozzle 22 is an example of a second gas nozzle. The gas nozzle 21, the gas nozzle 22, and the gas nozzle 23 are formed of, for example, quartz. The gas supply 20 may further include another gas nozzle.

The gas nozzle 21 has a letter-L shape that penetrates the side wall of the manifold 3 inward, is bent upward, and extends vertically. The vertical part of the gas nozzle 21 is provided in the processing space A1. A plurality of gas holes 21a are provided in the vertical part of the gas nozzle 21. The plurality of gas holes 21a are provided at predetermined intervals along the extending direction of the gas nozzle 21. Each gas hole 21a is directed to, for example, the center CT of the processing chamber 1.

A supply path L1 is connected to the gas nozzle 21. The supply path L1 is provided with a supply source G1 of a first processing gas, a mass flow controller F1, and an opening/closing valve V1 in order from the upstream side to the downstream side in the gas flow direction. The supply timing of the first processing gas in the supply source G1 is controlled by the opening/closing valve V1, and the flow rate thereof is adjusted to a predetermined flow rate by the mass flow controller F1. The first processing gas flows into the gas nozzle 21 through the supply path L1, and is discharged in the horizontal direction from the plurality of gas holes 21a toward the center CT of the processing chamber 1.

The gas nozzle 22 has a letter-L shape that penetrates the side wall of the manifold 3 inward, is bent upward, and extends vertically. The vertical part of the gas nozzle 22 is provided in a plasma formation space A2 described later. A plurality of gas holes 22a are provided in the vertical part of the gas nozzle 22. The plurality of gas holes 22a are provided at predetermined intervals along the extending direction of the gas nozzle 22. Each gas hole 22a is directed to, for example, the center CT of the processing chamber 1.

A supply path L2 is connected to the gas nozzle 22. The supply path L2 is provided with a supply source G2 of a second processing gas, a mass flow controller F2, and an opening/closing valve V2 in order from the upstream side to the downstream side in the gas flow direction. The supply timing of the second processing gas in the supply source G2 is controlled by the opening/closing valve V2, and the flow rate thereof is adjusted to a predetermined flow rate by the mass flow controller F2. The second processing gas flows into the gas nozzle 22 through the supply path L2, and is discharged in the horizontal direction from the plurality of gas holes 22a toward the center CT of the processing chamber 1.

The gas nozzle 22 is configured to heat the second processing gas in the gas nozzle 22. Details of the gas nozzle 22 will be described later.

The gas nozzle 23 has a straight tube shape penetrating the side wall of the manifold 3 and extending horizontally. The gas nozzle 23 is connected to a supply source G3 of an inert gas. An end part of the gas nozzle 23 is provided in the processing chamber 1. The end part of the gas nozzle 23 is open, and the inert gas is supplied into the processing chamber 1 through the opening. The inert gas is, for example, nitrogen (N₂). The inert gas may be argon (Ar).

The plasma forming part 30 is provided on a part of the side wall of the processing chamber 1. The plasma forming part 30 forms a plasma from the second processing gas supplied from the gas nozzle 22. The plasma forming part 30 includes a plasma partition wall 32, a pair of plasma electrodes 33, a power supply line 34, an RF power source 35, and an insulating protection cover 36.

The plasma partition wall 32 is airtightly welded to the outer wall of the processing chamber 1. The plasma partition wall 32 is formed of, for example, quartz. The plasma partition wall 32 has a box-like cross-sectional shape and covers an opening 31 formed in the side wall of the processing chamber 1. The opening 31 is formed in an elongated state extending in the vertical direction so as to be able to cover all substrates W that are supported on the boat 5 in the vertical direction. The plasma partition wall 32 forms the plasma formation space A2. The plasma formation space A2 communicates with the processing space A1. The plasma formation space A2 is provided with the gas nozzle 22. In the plasma formation space A2, a plasma is formed from the second processing gas supplied from the gas nozzle 22.

The pair of plasma electrodes 33, each of which has an elongated shape, are situated on the outer surfaces of facing walls of the plasma partition wall 32 such that the pair of plasma electrodes 33 face each other along the vertical direction. The power supply line 34 is connected to the lower end of each plasma electrode 33.

The power supply line 34 electrically connects each plasma electrode 33 and the RF power source 35 with each other. For example, one end of the power supply line 34 is connected to the lower end of each plasma electrode 33 on the side of a shorter side of the plasma electrode 33, and the other end of the power supply line 34 is connected to the RF power source 35.

The RF power source 35 is electrically connected to the lower end of each plasma electrode 33 via the power supply line 34. The RF power source 35 supplies, for example, a 13.56 MHz RF power to the pair of plasma electrodes 33. Thus, the RF power is applied to the plasma formation space A2 defined by the plasma partition wall 32.

The insulating protection cover 36 is attached to the outer side of the plasma partition wall 32 so as to cover the plasma partition wall 32. A refrigerant path (not shown) is provided inside the insulating protection cover 36. A refrigerant, such as nitrogen or the like, that is cooled is flowed through the refrigerant path to cool the plasma electrodes 33. A shield (not shown) may be provided between the plasma electrodes 33 and the insulating protection cover 36 so as to cover the plasma electrodes 33. The shield is formed of a good conductor such as metals and the like, and is electrically grounded.

The gas exhaust part 40 includes a gas exhaust port 41. The gas exhaust port 41 is provided in a side wall part of the processing chamber 1 facing the opening 31. The gas exhaust port 41 is formed in an elongated state extending vertically to correspond to the boat 5. A cover member 42 formed in a letter-U shaped cross-section shape to cover the gas exhaust port 41 is attached to a part of the processing chamber 1 corresponding to the gas exhaust port 41. The cover member 42 extends upward along the side wall of the processing chamber 1. A gas exhaust pipe 43 is connected to a lower part of the cover member 42. The gas exhaust pipe 43 is provided with a pressure regulating valve 44 and a vacuum pump 45 in order from the upstream to the downstream in the gas flow direction. The gas exhaust part 40 operates the pressure regulating valve 44 and the vacuum pump 45 under the control of the controller 90, to regulate the pressure in the processing chamber 1 by the pressure regulating valve 44 while aspirating a gas in the processing chamber 1 into the vacuum pump 45. The chamber heating part 50 includes a heater 51. The heater 51 has a cylindrical shape surrounding the processing chamber 1 on the outer side of the processing chamber 1 in the radial direction. The heater 51 heats the entire circumference of the side of the processing chamber 1, thereby heating the interior of the processing chamber 1 and each substrate W housed in the processing chamber 1.

The controller 90 is an electronic circuit, such as a Central Processing Unit (CPU), a Field Programmable Gate Array (FPGA), an Application Specific Integrated Circuit (ASIC), and the like. The controller 90 performs various control operations described herein by executing instruction codes stored in a memory or by being designed as a circuit for specific applications.

### [Gas Nozzle]

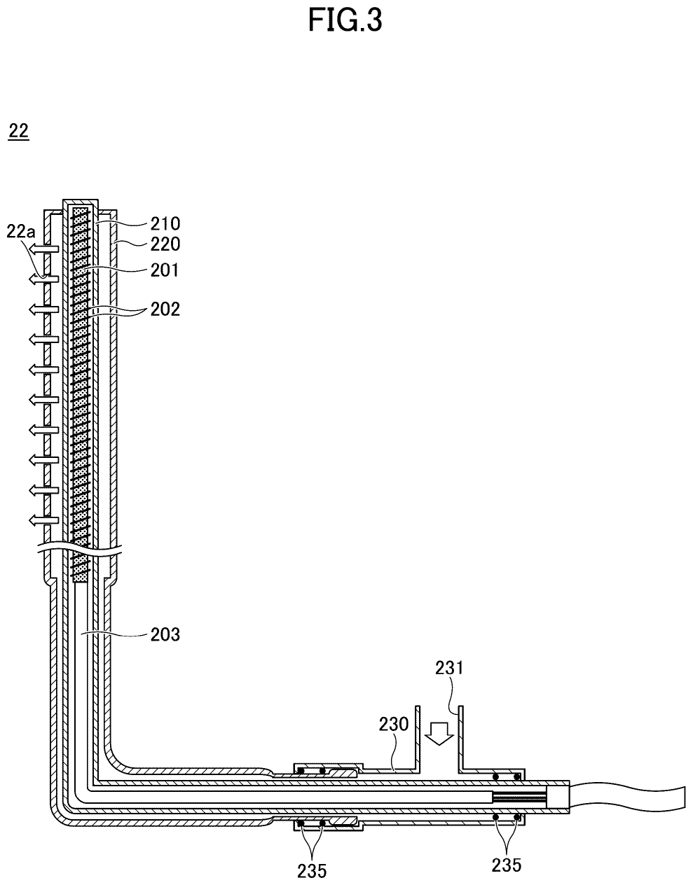

Referring to FIG. 3, an example of the gas nozzle 22 provided in the processing apparatus 100 will be described. FIG. 3 is a cross-sectional view showing an example of the gas nozzle 22 provided in the processing apparatus 100 according to the embodiment.

The gas nozzle 22 includes an inner tube 210, an outer tube 220, and an adapter 230. The outer tube 220 and the adapter 230 are connected via a seal 235. The inner tube 210 is situated inside the outer tube 220 and the adapter 230. An alumina core 201, a heating element 202, and a flexible cable 203 are provided inside the inner tube 210. The heating element 202 is wound around the alumina core 201. The flexible cable 203 connects the heating element 202 and a heater power source (not shown) with each other. The heater power source supplies power to the heating element 202 through the flexible cable 203. Thus, the heating element 202 generates heat and the alumina core 201 is heated.

The second processing gas supplied from a supply port 231 of the adapter 230 passes through the space between the inner tube 210 and the adapter 230 and the space between the inner tube 210 and the outer tube 220, and is discharged from the gas holes 22a. With power supplied from the heater power source to the heating element 202, the second processing gas is heated, and the heated second processing gas is discharged from the gas holes 22a. In this way, the gas nozzle 22 includes the outer tube 220 in which the second processing gas flows, and a gas heater situated in the outer tube 220 to heat the second processing gas flowing in the outer tube 220. The gas heater includes the alumina core 201 and the heating element 202. The gas heater is situated in a part of the outer tube 220 that is situated in the plasma formation space A2.

According to the processing apparatus 100 according to the embodiment, the gas nozzle 22 includes the gas heater configured to heat the second processing gas in the gas nozzle 22, and the gas nozzle 22 is disposed in the plasma formation space A2. In this case, it is possible to activate the second processing gas in the gas nozzle 22 by heating by the gas heater, to supply the activated second processing gas into the plasma formation space A2, and to form a plasma from the activated second processing gas in the plasma formation space A2. Therefore, the reactivity of the second processing gas is improved. Further, since the second processing gas in the gas nozzle 22 can be heated by the gas heater provided separately from the chamber heating part 50, it is possible to lower the temperature to which the chamber heating part 50 is set. Therefore, it is possible to reduce the thermal history to be received by the substrates W processed in the processing space A1. Thus, the processing apparatus 100 according to the embodiment can achieve both of reduction of a thermal history and improvement of the reactivity of the second processing gas.

### [Processing Gas]

The first processing gas and the second processing gas used in the processing apparatus 100 will be described below.

For example, when the process to be performed in the processing space A1 of the processing apparatus 100 is a film forming process, the first processing gas may be a raw material gas, and the second processing gas may be a first reaction gas that reacts with the raw material gas to produce a reaction product. The type of the raw material gas is not particularly limited, and is, for example, a silicon-containing gas, such as dichlorosilane (DCS) and the like. The type of the first reaction gas is not particularly limited, and is, for example, a nitriding gas, such as ammonia (NH₃) and the like, and an oxidation gas, such as oxygen (O₂) and the like.

For example, when the process to be performed in the processing space A1 of the processing apparatus 100 is an etching process, the first processing gas may be an etching gas, and the second processing gas may be a second reaction gas for promoting etching by the etching gas. The type of the etching gas is not particularly limited, and is, for example, a fluorine-containing gas, such as hydrogen fluoride (HF) and the like. The type of the second reaction gas is not particularly limited, and is, for example, ammonia.

### [Processing Method]

### First Example

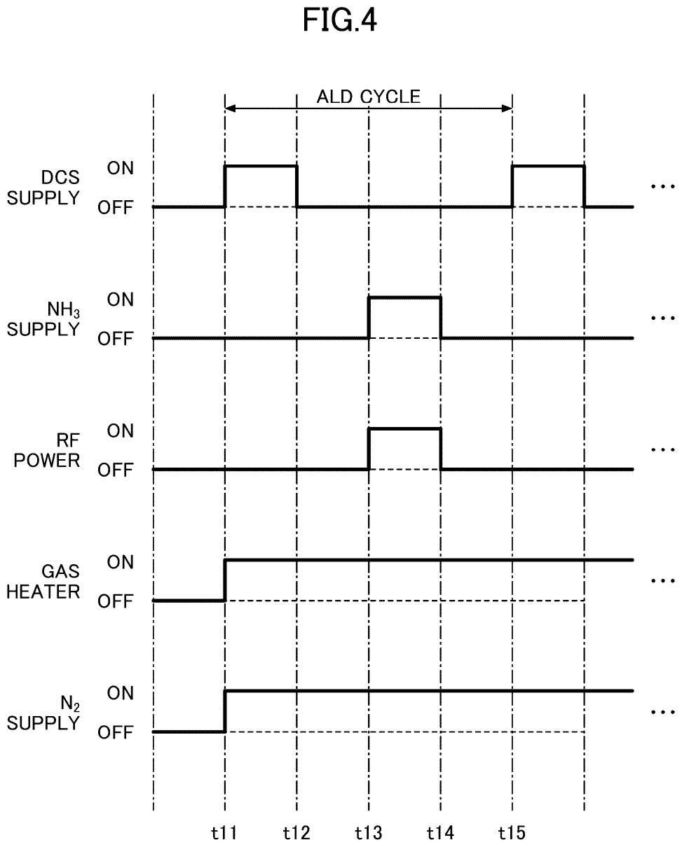

Referring to FIG. 4, a method for forming a silicon nitride film by Atomic Layer Deposition (ALD) in which dichlorosilane and ammonia are non-simultaneously supplied will be described as a processing method according to a first example of the embodiment. Dichlorosilane is an example of the first processing gas. Ammonia is an example of the second processing gas. FIG. 4 is a timing chart showing the processing method according to the first example of the embodiment. The processing method according to the first example of the embodiment is performed under the control of the controller 90.

First, the controller 90 loads the boat 5 holding a plurality of substrates W into the processing chamber 1 by elevating the arm 13, and airtightly shuts and closely seals the opening at the lower end of the processing chamber 1 with the cover 9. Next, the controller 90 controls the gas exhaust part 40 such that the interior of the processing chamber 1 becomes at a set pressure, and controls the chamber heating part 50 such that the interior of the processing chamber 1 becomes at a desired temperature.

Next, in the processing chamber 1, the controller 90 performs a film forming process to form a silicon nitride film on the surface of each substrate w by ALD in which dichlorosilane and ammonia are supplied non-simultaneously.

At a timing t11, the gas nozzle 21 starts supplying dichlorosilane into the processing space A1. Thus, dichlorosilane is adsorbed to the surface of each substrate W. At the timing t11, the gas heater starts heating the gas nozzle 22. The gas heater may be set to a temperature higher than, for example, the temperature to which the chamber heating part 50 is set. At the timing t11, the gas nozzle 23 starts supplying nitrogen to the processing space A1.

At a timing t12, the gas nozzle 21 stops supplying dichlorosilane to the processing space A1. The heating of the gas nozzle 22 by the gas heater is continued also at and after the timing t12. The heating of the gas nozzle 22 by the gas heater is continued until, for example, the film forming process is completed. The supply of nitrogen from the gas nozzle 23 into the processing space A1 is continued also at and after the timing t12. The supply of nitrogen from the gas nozzle 23 into the processing space A1 is continued until, for example, the film forming process is completed. For the period from the timing t12 to a timing t13, the supply of nitrogen from the gas nozzle 23 into the processing space A1 is continued. Therefore, the dichlorosilane remaining in the processing space A1 is replaced with nitrogen. That is, purging is performed in the processing space A1.

At the timing t13, the gas nozzle 22 starts supplying ammonia to the plasma formation space A2. Here, since the gas nozzle 22 is continuously heated by the gas heater, the ammonia is heated in the gas nozzle 22 and supplied into the plasma formation space A2. At the timing t13, the plasma forming part 30 starts supplying RF power. Thus, a plasma is formed from the heated ammonia in the plasma formation space A2. Active species, such as radicals and the like, contained in the plasma are supplied from the plasma formation space A2 into the processing space A1. Therefore, dichlorosilane adsorbed to the surface of each substrate W is nitrided.

At a timing t14, the gas nozzle 22 stops supplying ammonia into the plasma formation space A2. At the timing t14, the plasma forming part 30 stops supplying RF power. For the period from the timing t14 to a timing t15, the supply of nitrogen from the gas nozzle 23 into the processing space A1 is continued. Therefore, the ammonia remaining in the processing space A1 is replaced with nitrogen. That is, purging is performed in the processing space A1.

Next, with the process from the timing t11 to the timing t15 regarded as an ALD cycle, the ALD cycle is repeated a plurality of times. Thus, a silicon nitride film is formed on the surface of each substrate W held on the boat 5.

Next, the controller 90 raises the pressure in the processing chamber 1 to an open-air pressure, lowers the temperature in the processing chamber 1 to an unloading temperature, and then moves down the arm 13 to unload the boat 5 from the processing chamber 1. In this way, the film forming process on the plurality of substrates W is completed.

According to the processing method according to the first example of the embodiment, ammonia is activated in the gas nozzle 22 by heating by the gas heater, the activated ammonia is supplied into the plasma formation space A2, and a plasma is formed from the activated ammonia in the plasma formation space A2. Therefore, the reactivity of the ammonia is improved. Moreover, since the ammonia in the gas nozzle 22 can be heated by the gas heater provided separately from the chamber heating part 50, it is possible to lower the temperature to which the chamber heating part 50 is set. Therefore, it is possible to reduce a thermal history received by the substrates W processed in the processing space A1. Thus, the processing method according to the first example of the embodiment can achieve both of reduction of a thermal history and improvement of the reactivity of ammonia.

In the example shown in FIG. 4, the gas nozzle 22 is heated by the gas heater from the timing t11 to the end of the film forming process. However, the timing to heat the gas nozzle 22 by the gas heater is not limited to this. For example, the gas nozzle 22 may be heated by the gas heater at the same timing as the timing at which the gas nozzle 22 supplies ammonia into the plasma formation space A2. That is, the gas nozzle 22 may be heated by the gas heater for the period from the timing t13 to the timing t14. For example, heating of the gas nozzle 22 by the gas heater may be started before the timing t11.

### Example 2

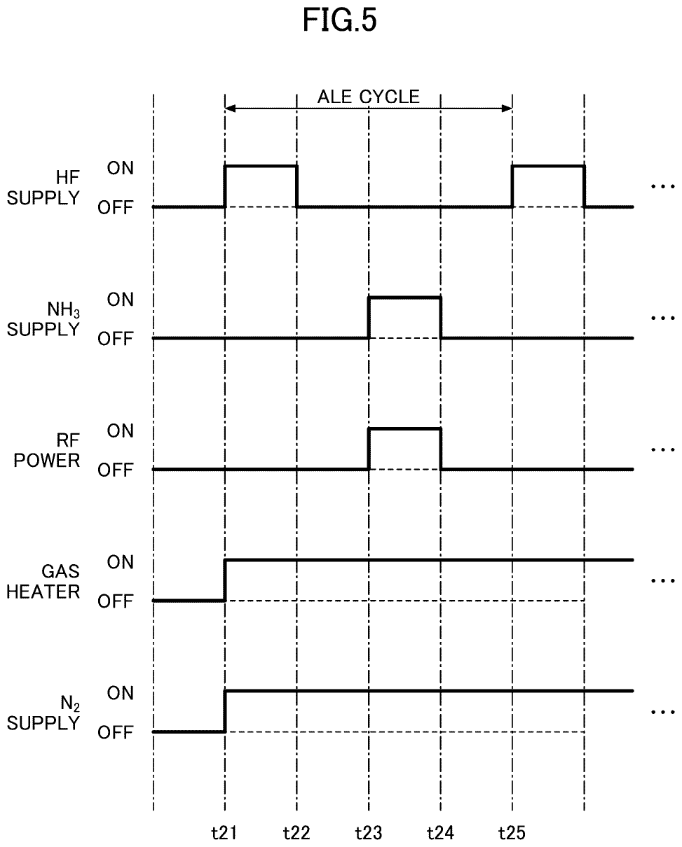

Referring to FIG. 5, a method for etching a boron nitride (BN) film by Atomic Layer Etching (ALE) in which hydrogen fluoride and ammonia are non-simultaneously supplied will be described as the processing method according to a second example of the embodiment. Hydrogen fluoride is an example of the first processing gas. Ammonia is an example of the second processing gas. FIG. 5 is a timing chart showing the processing method according to the second example of the embodiment. The processing method according to the second example of the embodiment is performed under the control of the controller 90.

First, the controller 90 loads the boat 5 holding a plurality of substrates W into the processing chamber 1 by elevating the arm 13, and airtightly shuts and closely seals the opening at the lower end of the processing chamber 1 with the cover 9. Each substrate W has, for example, a boron nitride film on its surface. Next, the controller 90 controls the gas exhaust part 40 such that the interior of the processing chamber 1 becomes at a set pressure, and controls the chamber heating part 50 such that the interior of the processing chamber 1 becomes at a desired temperature.

Next, in the processing chamber 1, the controller 90 performs an etching process for etching the boron nitride film on the surface of each substrate W by ALE in which hydrogen fluoride and ammonia are supplied non-simultaneously.

At a timing t21, the gas nozzle 21 starts supplying hydrogen fluoride into the processing space A1. As a result, the surface layer of the boron nitride film formed on the surface of each substrate W is fluorinated, and a fluoride layer is formed. At the timing t21, the gas heater starts heating the gas nozzle 22. The temperature to which the gas heater is set may be higher than, for example, the temperature to which the chamber heating part 50 is set. At the timing t21, the gas nozzle 23 starts supplying nitrogen into the processing space A1.

At a timing t22, the gas nozzle 21 stops supplying hydrogen fluoride into the processing space A1. The heating of the gas nozzle 22 by the gas heater is continued also at and after the timing t22. The heating of the gas nozzle 22 by the gas heater is continued until, for example, the etching process is completed. The supply of nitrogen from the gas nozzle 23 into the processing space A1 is continued also at and after time t22. The supply of nitrogen from the gas nozzle 23 into the processing space A1 is continued until, for example, the etching process is completed. For the period from the timing t22 to a timing t23, the supply of nitrogen from the gas nozzle 23 into the processing space A1 is continued. Therefore, hydrogen fluoride remaining in the processing space A1 is replaced with nitrogen. That is, purging is performed in the processing space A1.

At the timing t23, the gas nozzle 22 starts supplying ammonia into the plasma formation space A2. Here, since heating of the gas nozzle 22 by the gas heater is continued, ammonia is heated in the gas nozzle 22 and supplied into the plasma formation space A2. At the timing t23, the plasma forming part 30 starts supplying RF power. Thus, a plasma is formed from the heated ammonia in the plasma formation space A2. Active species, such as radicals and the like, contained in the plasma are supplied from the plasma formation space A2 into the processing space A1. When the active species are supplied to the fluoride layer, the fluoride layer changes to ammonium borofluoride (NH BF) or the like. Ammonium borofluoride is sublimated and released from the surface of each substrate W. Thus, the fluoride layer is removed from the surface of each substrate W, and the boron nitride film is etched.

At a timing t24, the gas nozzle 22 stops supplying ammonia into the plasma formation space A2. At the timing t24, the plasma forming part 30 stops supplying RF power. For the period from the timing t24 to a timing t25, the supply of nitrogen from the gas nozzle 23 into the processing space A1 is continued. Therefore, ammonia, ammonium borofluoride and the like remaining in the processing space A1 are replaced with nitrogen. That is, purging is performed in the processing space A1.

Next, with the process from the timing t21 to the timing t25 regarded as an ALE cycle, the ALE cycle is repeated a plurality of times. Thus, the boron nitride film formed on the surface of each substrate W held on the boat 5 is etched.

Next, the controller 90 raises the pressure in the processing chamber 1 to an open-air pressure, lowers the temperature in the processing chamber 1 to an unloading temperature, and then moves down the arm 13 to unload the boat 5 from the processing chamber 1. In this way, the etching process on the plurality of substrates W is completed.

According to the processing method according to the second example of the embodiment, ammonia is activated in the gas nozzle 22 by heating by the gas heater, the activated ammonia is supplied into the plasma formation space A2, and a plasma is formed from the activated ammonia in the plasma formation space A2. Therefore, the reactivity of ammonia is improved. Moreover, since the ammonia in the gas nozzle 22 can be heated by the gas heater provided separately from the chamber heating part 50, it is possible to lower the temperature to which the chamber heating part 50 is set. Therefore, it is possible to reduce a thermal history received by each substrate W processed in the processing space A1. Thus, the processing method according to the second example of the embodiment can achieve both of reduction of a thermal history and improvement of the reactivity of ammonia.

In the example shown in FIG. 5, the gas nozzle 22 is heated by the gas heater from the timing t21 to the end of the etching process. However, the timing to heat the gas nozzle 22 by the gas heater is not limited to this. For example, the gas nozzle 22 may be heated by the gas heater at the same timing as the timing at which the gas nozzle 22 supplies ammonia into the plasma formation space A2. That is, for the period from the timing t23 to the timing t24, the gas nozzle 22 may be heated by the gas heater. For example, heating of the gas nozzle 22 by the gas heater may be started before the timing t21.

The embodiments disclosed herein should be considered to be exemplary in all respects and not restrictive. Various omissions, replacements, and modification are applicable to the above-described embodiments without departing from the scope and spirit of the appended claims.

In the above embodiments, a case in which the processing apparatus uses a Capacitively Coupled Plasma (CCP) has been described. However, this is non-limiting. For example, the processing apparatus may use an Inductively Coupled Plasma (ICP) or a microwave discharge plasma.

According to the present disclosure, both of reduction of a thermal history and improvement of the reactivity of a processing gas can be achieved.

What is claimed is:

1. A processing apparatus, comprising:
a processing chamber forming a processing space in which a plurality of substrates are processed;
a plasma forming part configured to form a plasma in a plasma formation space communicating with the processing space;
a first gas nozzle configured to supply a first processing gas into the processing space; and
a second gas nozzle configured to supply a second processing gas into the plasma formation space,
wherein the second gas nozzle includes a gas heater configured to heat the second processing gas in the second gas nozzle.

2. The processing apparatus according to claim 1, further comprising:
a controller,
wherein the controller controls:
loading the plurality of substrates into the processing space;
the first gas nozzle supplying the first processing gas into the processing space;
the gas heater heating the second processing gas in the second gas nozzle;
the second gas nozzle supplying the second processing gas heated, into the plasma formation space; and
the plasma forming part forming the plasma from the second processing gas supplied into the plasma formation space.

3. The processing apparatus according to claim 2, further comprising:
a chamber heating part provided around the processing chamber and configured to heat an interior of the processing chamber.

4. The processing apparatus according to claim 3,
wherein a temperature to which the gas heater is set is higher than a temperature to which the chamber heating part is set.

5. The processing apparatus according to claim 1,
wherein the first processing gas is a raw material gas, and
the second processing gas is a first reaction gas that reacts with the raw material gas to produce a reaction product.

6. The processing apparatus according to claim 5,
wherein the raw material gas is a silicon-containing gas, and
the first reaction gas is a nitriding gas or an oxidation gas.

7. The processing apparatus according to claim 1,
wherein the first processing gas is an etching gas, and
the second processing gas is a second reaction gas that promotes etching by the etching gas.

8. The processing apparatus according to claim 7,
wherein the etching gas is hydrogen fluoride, and
the second reaction gas is ammonia.

9. A processing method, comprising:
loading a plurality of substrates into a processing space;
supplying a first processing gas from a first gas nozzle into the processing space;
supplying a second processing gas from a second gas nozzle into a plasma formation space communicating with the processing space;
heating the second processing gas in the second gas nozzle by a gas heater included in the second gas nozzle; and
forming a plasma from the second processing gas supplied into the plasma formation space.
